(19) United States
(12) Patent Application Publication
(10) Pub. No.: US 2014/0175511 A1
(43) Pub. Date: Jun. 26, 2014

(54) AVALANCHE PHOTODIODE

(71) Applicant: Electronics and Telecommunications Research Institute, Daejeon (KR)

(72) Inventors: Jae-Sik SIM, Daejeon (KR); Bongki Mheen, Daejeon (KR); Kisoo Kim, Seoul (KR); Myoungsook Oh, Daejeon (KR)

(73) Assignee: Electronics and Telecommunications Research Institute, Daejeon (KR)

(21) Appl. No.: 13/950,454

(22) Filed: Jul. 25, 2013

(30) Foreign Application Priority Data
Dec. 24, 2012 (KR) 10-2012-0152403

(51) Int. Cl. H01L 31/107

(52) U.S. Cl. CPC H01L 31/1075
USPC 257/186; 257/436

(57) ABSTRACT

An avalanche photodiode according to the inventive concept includes a substrate, light absorption layers on the substrate, clad layers on the light absorption layers, and active regions in the clad layers. The light absorption layers, the clad layers, and the active regions constitute unit cells. Each of the unit cells has a fan-shape.

### CROSS-REFERENCE TO RELATED APPLICATIONS

This U.S. non-provisional patent application claims priority under 35 U.S.C. §119 to Korean Patent Application No. 10-2012-0152403, filed on Dec. 24, 2012, the entirety of which is incorporated by reference herein.

### BACKGROUND

The inventive concept relates to a photodiode and, more particularly, to an avalanche photodiode.

As high speed and large capacity optical communication system and image processing system are being demanded, various researches are being conducted for light detectors essentially used in their systems.

After light is irradiated to an object far away, light reflected or scattered from the object may be concentrated through a lens and then the concentrated light may be detected by the light detector. The light incident on the light detector may be converted into an electrical signal through a photodiode and then the electrical signal may be transmitted to a light receiver through an amplifier. Photodiodes may be categorized as any one of a p-type/intrinsic type/n-type (PIN) photodiode, a PN photodiode, and an avalanche photodiode.

The PIN or PN photodiode does not have an internal gain. Thus, a sensitivity of the PIN or PN photodiode may be worse than that of the avalanche photodiode. The PIN or PN photodiode may be combined with a pre-amplifier or a trans-impedance amplifier (TIA), so as to be commercialized. However, since the amplifier amplifies a noise, it may function as a factor reducing a receiving sensitivity of the PIN or PN photodiode.

The avalanche photodiode (APD) may prevent the reduction of the receiving sensitivity by a gain. The gain of a signal may be obtained by avalanche multiplication of the APD. A high electric field may be applied to holes or electrons generated in a light absorption layer to induce the avalanche multiplication. The APD has a more complicated structure than the PIN or PN photodiode. Additionally, the APD should be designed to have a planar shape for improving its reliability. When the APD amplifies a signal, a noise may additionally occur. However, the gain of the signal may be greater than the occurring noise, such that a signal-to-noise ratio (SNR) of the APD may be better than that of the PIN or PN photodiode. Thus, the APD may have the receiving sensitivity better than that of the PIN or PN photodiode.

The avalanche multiplication should be uniformly induced in an amplification layer of the APD in order that the reduction of the receiving sensitivity is prevented using the gain of the APD. If the intensity of the electric field is strong in a specific region to concentrate the avalanche in the specific region, it is difficult to obtain a uniform amplification characteristic. This case is generally called ‘edge breakdown’.

Additionally, a noise characteristic may be greater than the secured gain characteristic by the edge breakdown, such that the SNR of the APD may be worse. Thus, a uniform avalanche gain should be obtained with suppression of the noise. To achieve this, a device may be designed for properly preventing the edge breakdown.

In a general APD, as a size of a receiving region increases, a capacitance value may increase. A bandwidth may be reduced by the increased capacitance value. Thus, the receiving sensitivity of the general APD may be deteriorated.

### SUMMARY

Embodiments of the inventive concept may provide avalanche photodiodes capable of reducing a capacitance value according to increase of a receiving region.

Embodiments of the inventive concept may also provide avalanche photodiodes capable of increasing or maximizing a receiving sensitivity.

In an aspect, an avalanche photodiode includes: a substrate; light absorption layers on the substrate; clad layers disposed on the light absorption layers, respectively; and active regions disposed in the clad layers, respectively. The light absorption layers, the clad layers, and the active regions constitute unit cells; and each of the unit cells has a fan-shape.

In an embodiment, the avalanche photodiode may further include: an isolation insulating layer separating the unit cells from each other.

In an embodiment, the unit cells may congregate in a circle.

In an embodiment, the unit cells may further include guarding regions spaced apart from the active regions and disposed in the clad layers.

In an embodiment, the guarding regions may be disposed at arcs of the fan-shapes of the unit cells, respectively.

In an embodiment, the guarding regions and the isolation insulating layer may surround the active regions in a plan view.

In an embodiment, the guarding regions may surround the active regions of the fan-shapes, respectively.

In an embodiment, the substrate, the light absorption layer, and the clad layer may be doped with dopants of a first conductivity type; and the active region and the guarding region may be doped with dopants of a second conductivity type.

In an embodiment, the isolation insulating layer may include a silicon nitride layer.

In an embodiment, each of the unit cells may further include: a buffer layer between the light absorption layer and the clad layer; and a grading layer between the buffer layer and the light absorption layer.

In an embodiment, the substrate, the buffer layer, and the clad layer may include InP; and the grading layer and the light absorption layer may include InGaAsP.

In an embodiment, the avalanche photodiode may further include: an upper electrode on the active region; and a lower electrode disposed under the substrate, the lower electrode opposite to the upper electrode.

### BRIEF DESCRIPTION OF THE DRAWINGS

The inventive concept will become more apparent in view of the attached drawings and accompanying detailed description.

FIG. 1 is a plan view illustrating an avalanche photodiode according to a first embodiment of the inventive concept;

FIGS. 2A and 2B are cross-sectional views taken along a line I-I′ of FIG. 1;

FIG. 3 is a plan view illustrating an avalanche photodiode according to a second embodiment of the inventive concept;

FIGS. 4A and 4B are cross-sectional views taken along a line II-II′ of FIG. 3;

FIG. 5 is a plan view illustrating an avalanche photodiode according to a third embodiment of the inventive concept;

FIGS. 6A and 6B are cross-sectional views taken along a line III-III′ of FIG. 5; and

FIG. 7 is a plan view illustrating a cell array including a cell of FIG. 5.

### DETAILED DESCRIPTION OF THE EMBODIMENTS

The inventive concept will now be described more fully hereinafter with reference to the accompanying drawings, in which exemplary embodiments of the inventive concept are shown. The advantages and features of the inventive concept and methods of achieving them will be apparent from the following exemplary embodiments that will be described in more detail with reference to the accompanying drawings. It should be noted, however, that the inventive concept is not limited to the following exemplary embodiments, and may be implemented in various forms. Accordingly, the exemplary embodiments are provided only to disclose the inventive concept and let those skilled in the art know the category of the inventive concept. In the drawings, embodiments of the inventive concept are not limited to the specific examples provided herein and are exaggerated for clarity.

The terminology used herein is for the purpose of describing particular embodiments only and is not intended to limit the invention. As used herein, the singular terms “a,” “an” and “the” are intended to include the plural forms as well, unless the context clearly indicates otherwise. As used herein, the term “and/or” includes any and all combinations of one or more of the associated listed items. It will be understood that when an element is referred to as being “connected” or “coupled” to another element, it may be directly connected or coupled to the other element or intervening elements may be present.

Similarly, it will be understood that when an element such as a layer, region or substrate is referred to as being “on” another element, it can be directly on the other element or intervening elements may be present. In contrast, the term “directly” means that there are no intervening elements. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

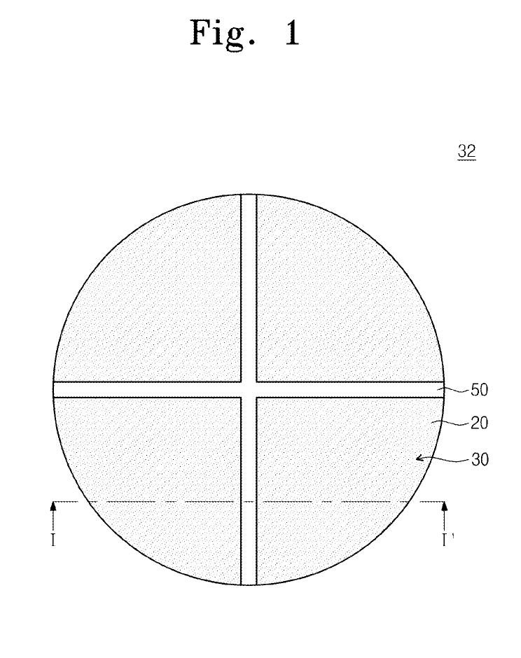

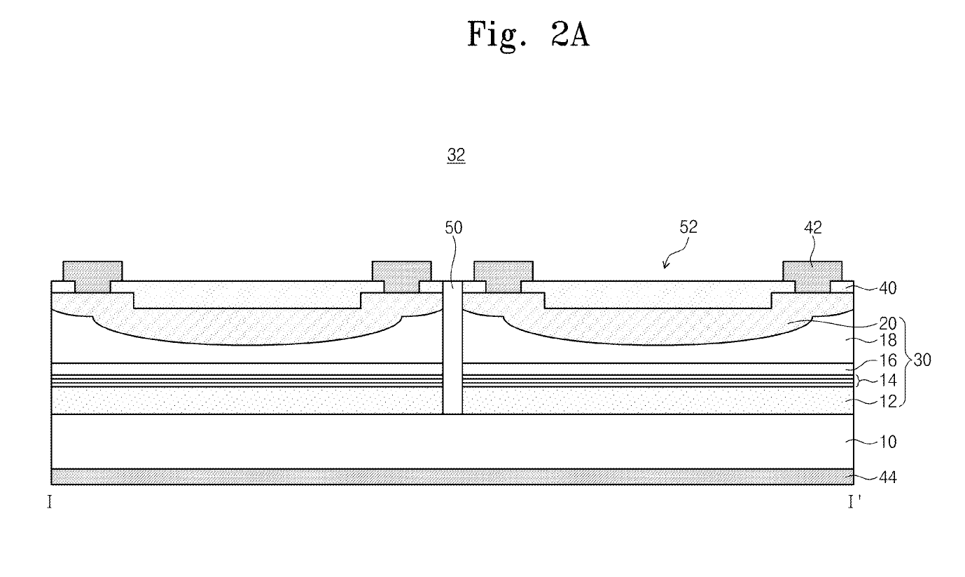

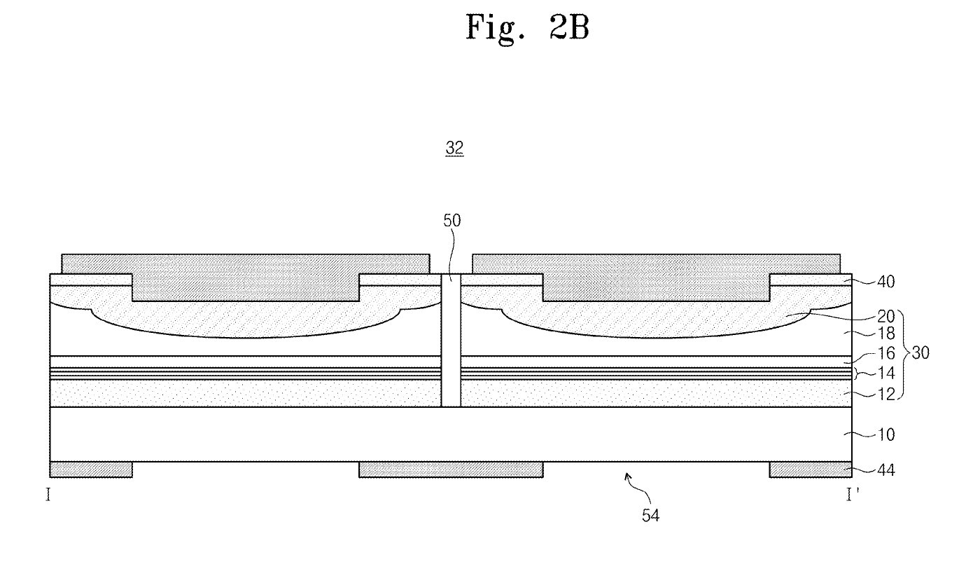

FIG. 1 is a plan view illustrating an avalanche photodiode according to a first embodiment of the inventive concept. FIGS. 2A and 2B are cross-sectional views taken along a line I-I′ of FIG. 1.

Referring to FIGS. 1, 2A, and 2B, an avalanche photodiode according to a first embodiment of the inventive concept may include a plurality of unit cells 30 having fan-shapes. The plurality of unit cells 30 may congregate in a circle to constitute a cell 32. The cell 32 may include four unit cells 30. However, the inventive concept is not limited thereto. An isolation insulating layer 50 may separate the unit cells 30 from each other. The unit cells 30 and the isolation insulating layer 50 may be disposed on a substrate 10. The isolation insulating layer 50 may include a silicon nitride layer. The substrate 10 may include a single crystalline n⁺-InP.

Each of the unit cells 30 may include a light absorption layer 12, a grading layer 14, a buffer layer 16, a clad layer 18, and an active region 20. The substrate 10, the light absorption layer 12, and the clad layer 18 may be doped with dopants of a first conductivity type, and the active region 20 may be doped with dopants of a second conductivity type. The light absorption layer 12 may include n-InGaAsP. The grading layer 14 may consist of a plurality of n-InGaAsP layers of which energy band gaps are different from each other. The substrate 10, the buffer layer 16, and the clad layer 18 may include n-InP. The buffer layer 16 may have an impurity concentration of about 3.0×10¹⁷ EA/cm³ to about 3.45×10¹⁷ EA/cm³. The clad layer 18 may have a thickness of about 3.5 μm to about 4.5 μm.

The active region 20 may be disposed in the clad layer 18. The active region 20 may include p⁺-InP. A passivation layer 40 may cover the active region 20. An upper electrode 42 may penetrate the passivation layer 40, so as to be connected to the active region 20. A lower electrode 44 may be disposed under the substrate 10. The avalanche photodiode may be a front-side type avalanche photodiode or a back-side type avalanche photodiode. As illustrated in FIG. 2A, the front-side type avalanche photodiode may have a front-side light receiving region 52 between the upper electrodes 42. In this case, the lower electrode 44 may be disposed on an entire surface of a back side of the substrate 10. On the contrary, as illustrated in FIG. 2B, the back-side type avalanche photodiode may have a back-side light receiving region 54 between the lower electrodes 44. In this case, the upper electrode 42 may fully cover the active region 20.

If light is incident from the outside of the avalanche photodiode, the light absorption layer 12 may generate electron-hole pairs by a visible ray of the incident light. The electron-hole pairs generated in the light absorption layer 12 may be separated from each other by a great electric field. The separated holes may be fast injected into the clad layer 18 through the grading layer 14, and the separated electrons may collect in the lower electrode 44. The holes injected in the clad layer 18 may be accelerated by a great electric field in the clad layer 18. The accelerated holes may cause impact ionization, and the ionized holes may additionally generate holes. In other words, holes may be additionally generated in the active region 20 by the great electric field of the clad layer 18, so that a photoelectric current may be amplified. The isolation insulating layer 50 may suppress concentration of an electric field at edges of the unit cells 30. An interface between the active region 20 and the clad layer 18 corresponds to a PN junction region. An avalanche breakdown at an edge portion of the PN junction may occur in advance of an avalanche breakdown at a center portion of the PN junction. The isolation insulating layer 50 may decrease the avalanche breakdown. The avalanche breakdown at the edge portion of the PN junction may be defined as an edge breakdown. As a result, the edge breakdown of the avalanche photodiode may be minimized in the unit cells 30 of the fan-shapes.

As a size of a receiving region of an avalanche photodiode increases, a capacitance value may increase. Since the increased capacitance value may reduce a bandwidth, a receiving sensitivity of the avalanche photodiode may be deteriorated. However, a size of each of the unit cells 30 may be reduced but the number of the unit cells 30 may increase. Thus, an entire receiving region of the avalanche photodiode may increase.

As a result, the avalanche photodiode according to the first embodiment of the inventive concept may increase or maximize the receiving sensitivity.

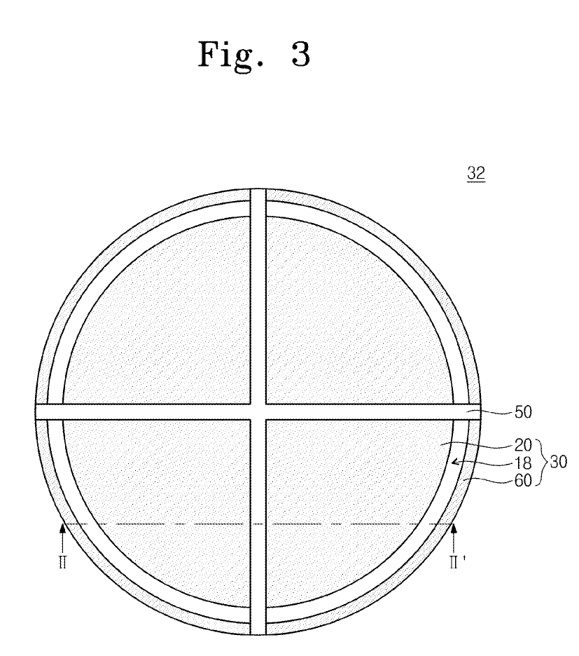

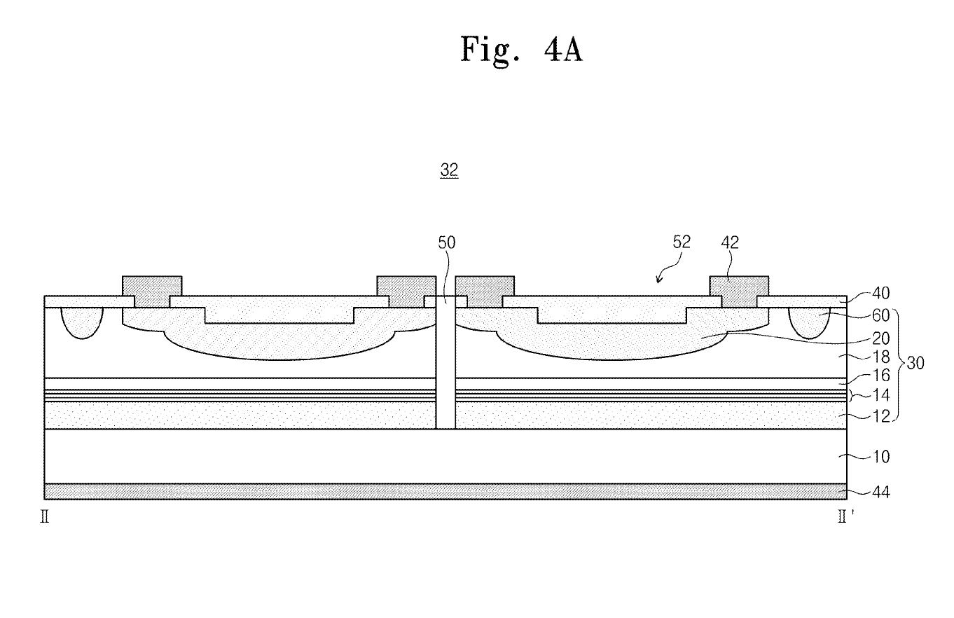

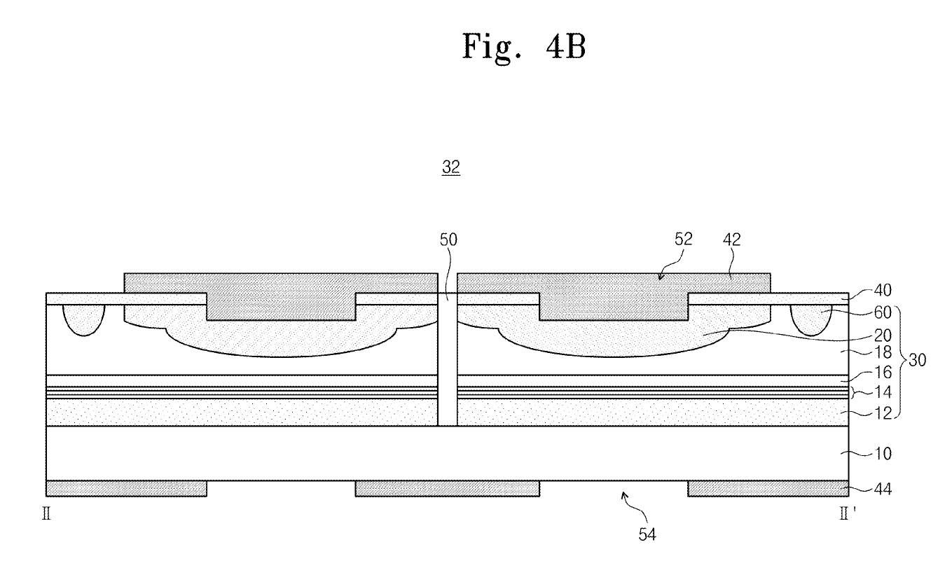

FIG. 3 is a plan view illustrating an avalanche photodiode according to a second embodiment of the inventive concept. FIGS. 4A and 4B are cross-sectional views taken along a line II-II′ of FIG. 3. An avalanche photodiode according to the second embodiment may further include guarding regions 60 surrounding the cell 32 of the first embodiment in FIGS. 1, 2A and 2B.

Referring to FIGS. 3, 4A, and 4B, the avalanche photodiode according to the second embodiment of the inventive concept may include the guarding regions 60 disposed at an edge of the cell 32. The cell 32 may include a plurality of unit cells 30.

The guarding region 60 may be disposed in the clad layer 18. The active regions 20 may be disposed to be adjacent to the guarding regions 60. However, the active regions 20 may be spaced apart from the guarding regions 60. The guarding region 60 may be disposed at a side of the active region 20 in the unit cell 30. For example, the guarding region 60 may be disposed at an arc of the fan-shape of the unit cell 30. The guarding regions 60 may be doped with dopants of the second conductivity type. The isolation insulating layer 50 may separate the guarding regions 60 from each other. The isolation insulating layer 50 may be disposed at another side of the active region 20. The guarding region 60 and the isolation insulating layer 50 may surround the active region 20 in a plan view. The isolation insulating layer 50 and the guarding region 60 may minimize the edge breakdown.

As a result, the avalanche photodiode according to the second embodiment of the inventive concept may increase or maximize the receiving sensitivity.

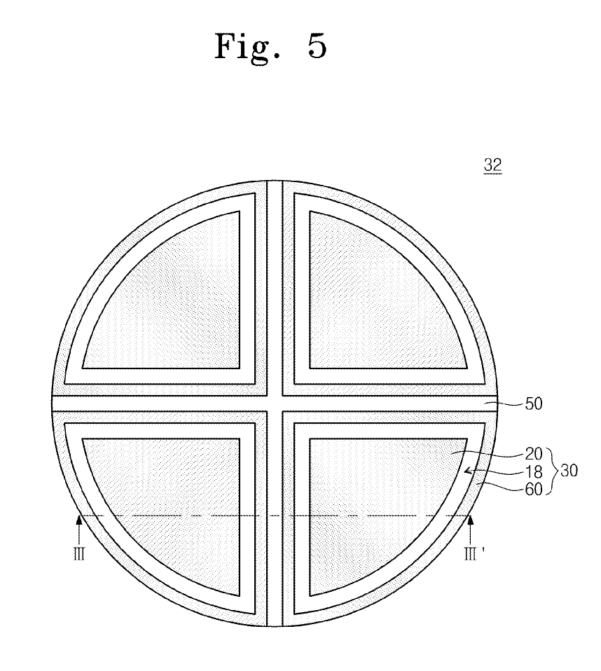

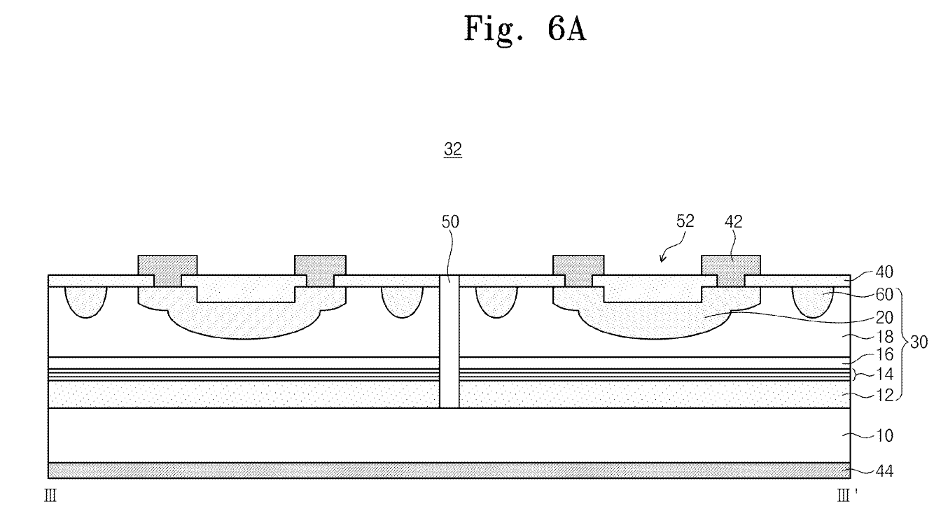

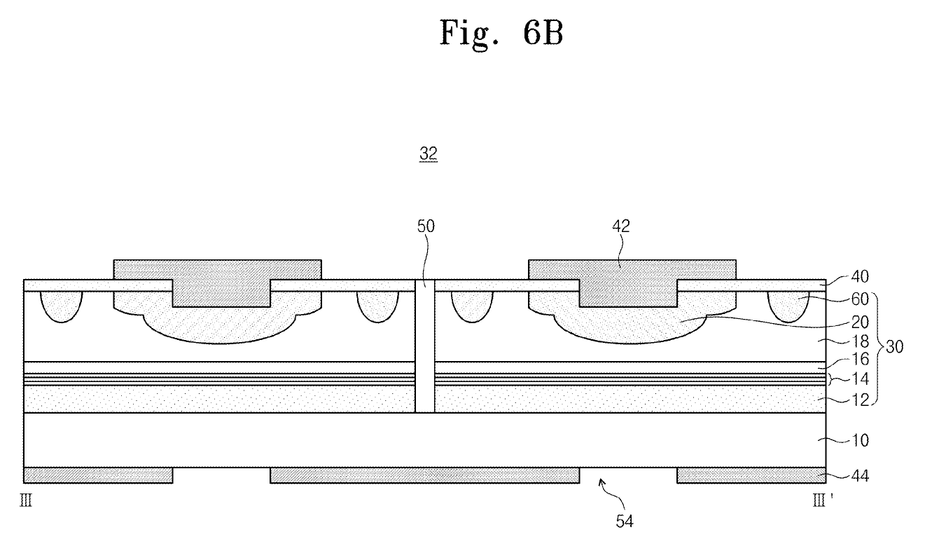

FIG. 5 is a plan view illustrating an avalanche photodiode according to a third embodiment of the inventive concept. FIGS. 6A and 6B are cross-sectional views taken along a line III-III′ of FIG. 5. An avalanche photodiode according to the third embodiment of the inventive concept may include a guarding region 60 disposed at an edge of the unit cell 30 in the first embodiment of FIGS. 1, 2A, and 2B.

Referring to FIGS. 5, 6A, and 6B, the avalanche photodiode according to the third embodiment of the inventive concept may include the guarding regions 60 at edges of the unit cells 30. The guarding region 60 may surround the active region 20 in a plan view. The unit cells 30 may be separated from each other by the isolation insulating layer 50. The guarding region 60 may be in contact with the isolation insulating layer 50 disposed between the unit cells 30. The active region 20 may be electrically separated from the guarding region 60. The guarding region 60 may suppress the edge breakdown of the active region 20. Thus, the avalanche photodiode according to the third embodiment of the inventive concept may increase or maximize the receiving sensitivity.

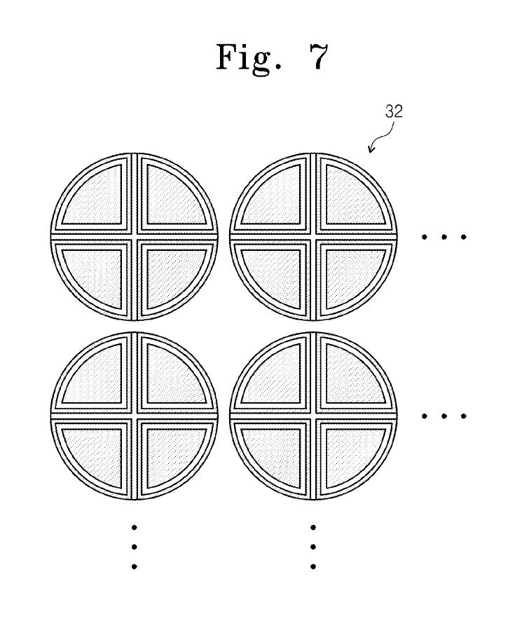

FIG. 7 is a plan view illustrating a cell array including cells 32 of FIG. 5.

Referring to FIG. 7, the cells 32 may be arranged in N×N array form in a plan view. The N×N array may include the cells 32 arranged along rows and columns Even though not shown in the drawings, the cells 32 of the N×N array may be arranged in zigzag form.

According to the aforementioned embodiments of the inventive concept, the cell of the avalanche photodiode may have a circular shape. The cell may include a plurality of the unit cells. The unit cells may have the fan-shapes. The isolation insulating layer may be disposed between unit cells. The unit cells of the fan-shapes may prevent or suppress the increase of the capacitance value caused by the increase of the receiving region. Additionally, the unit cells of the fan-shapes may decrease or minimize the edge breakdown of the avalanche photodiode. Thus, the avalanche photodiode according to the embodiments of the inventive concept may increase or maximize the receiving sensitivity thereof.

While the inventive concept has been described with reference to example embodiments, it will be apparent to those skilled in the art that various changes and modifications may be made without departing from the spirit and scope of the inventive concept. Therefore, it should be understood that the above embodiments are not limiting, but illustrative. Thus, the scope of the inventive concept is to be determined by the broadest permissible interpretation of the following claims and their equivalents, and shall not be restricted or limited by the foregoing description.

What is claimed is:

1. An avalanche photodiode comprising:
a substrate;
light absorption layers on the substrate;
clad layers disposed on the light absorption layers, respectively; and
active regions disposed in the clad layers, respectively,
wherein the light absorption layers, the clad layers, and the active regions constitute unit cells; and
wherein each of the unit cells has a fan-shape.

2. The avalanche photodiode of claim 1, further comprising:
an isolation insulating layer separating the unit cells from each other.

3. The avalanche photodiode of claim 2, wherein the unit cells congregate in a circle.

4. The avalanche photodiode of claim 3, wherein the unit cells further include guarding regions spaced apart from the active regions and disposed in the clad layers.

5. The avalanche photodiode of claim 4, wherein the guarding regions are disposed at arcs of the fan-shapes of the unit cells, respectively.

6. The avalanche photodiode of claim 5, wherein the guarding regions and the isolation insulating layer surround the active regions in a plan view.

7. The avalanche photodiode of claim 5, wherein the guarding regions surround the active regions of the fan-shapes, respectively.

8. The avalanche photodiode of claim 4, wherein the substrate, the light absorption layer, and the clad layer are doped with dopants of a first conductivity type; and
wherein the active region and the guarding region are doped with dopants of a second conductivity type.

9. The avalanche photodiode of claim 2, wherein the isolation insulating layer includes a silicon nitride layer.

10. The avalanche photodiode of claim 1, wherein each of the unit cells further comprises:
a buffer layer between the light absorption layer and the clad layer; and
a grading layer between the buffer layer and the light absorption layer.

11. The avalanche photodiode of claim 10, wherein the substrate, the buffer layer, and the clad layer include InP; and
wherein the grading layer and the light absorption layer include InGaAsP.

12. The avalanche photodiode of claim 1, further comprising:
an upper electrode on the active region; and
a lower electrode disposed under the substrate, the lower electrode opposite to the upper electrode.
